(19) United States
(12) Patent Application Publication
(10) Pub. No.: US 2012/0014078 A1
(43) Pub. Date: Jan. 19, 2012

(54) Electronic Component Structure and Electronic Device

(76) Inventor: Naonori Watanabe, Ome-shi (JP)

(21) Appl. No.: 13/028,980

(22) Filed: Feb. 16, 2011

(30) Foreign Application Priority Data
Jul. 13, 2010 (JP) 2010-158695

(51) Int. Cl. H05K 7/00; H05K 1/16

(52) U.S. Cl. 361/760; 174/260

(57) ABSTRACT

According to one embodiment, an electronic component structure includes an electronic component, an electrode, and a restriction portion. The electrode is connected to the electronic component in a multilayer state and comprises a plurality of solder regions on a side opposite to a side of the electronic component. Each of the solder regions is soldered to a substrate by separate solders. The restriction portion is connected to a periphery of the solder regions, and has a level difference relative to the solder regions.

### CROSS-REFERENCE TO RELATED APPLICATIONS

This application is based upon and claims the benefit of priority from Japanese Patent Application No. 2010-158695, filed Jul. 13, 2010, the entire contents of which are incorporated herein by reference.

### FIELD

Embodiments described herein relate generally to an electronic component structure and an electronic device.

### BACKGROUND

Conventionally, there is known an electronic device comprising an electronic component structure such as a semiconductor package and a substrate on which the electronic component structure is mounted, and in which a ground electrode for the electronic component structure is soldered to the substrate by a solder.

In such electronic device, when melted solder spreads over the electrode excessively due to the wettability of the solder while the electrode has been soldered to the substrate, the joining strength may be reduced because the thickness of the solder is reduced, or the electrode and the substrate cannot be soldered because the solder is absorbed toward the electronic component structure.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television device serving as an electronic device according to a first embodiment;

FIG. 2 is an exemplary longitudinal sectional view illustrating amounting state of a semiconductor package serving as an electronic component structure in the first embodiment;

FIG. 3 is an exemplary bottom view of a first electrode of the semiconductor package in the first embodiment;

FIG. 4 is an exemplary schematic diagram illustrating a mounting process of the semiconductor package to a substrate in the first embodiment;

FIG. 5 is an exemplary bottom view of a first electrode of a semiconductor package according to a second embodiment;

FIG. 6 is an exemplary longitudinal sectional view illustrating a mounting state of a semiconductor package according to a third embodiment;

FIG. 7 is an exemplary bottom view of a first electrode of the semiconductor package in the third embodiment;

FIG. 8 is an exemplary longitudinal sectional view illustrating a mounting state of a semiconductor package according to a fourth embodiment;

FIG. 9 is an exemplary longitudinal sectional view of a first electrode of the semiconductor package in the fourth embodiment;

FIG. 10 is an exemplary bottom view of the first electrode of the semiconductor package in the fourth embodiment;

FIG. 11 is an exemplary longitudinal sectional view of a first electrode of a semiconductor package according to a fifth embodiment;

FIG. 12 is an exemplary bottom view of a first electrode of a semiconductor package according to a sixth embodiment;

FIG. 13 is an exemplary perspective view of a personal computer serving as an electronic device according to a seventh embodiment; and

FIG. 14 is an exemplary perspective view of a magnetic disk device serving as an electronic device according to an eighth embodiment.

### DETAILED DESCRIPTION

In general, according to one embodiment, an electronic component structure comprises an electronic component, an electrode, and a restriction portion. The electrode is connected to the electronic component in a multilayer state and comprises a plurality of solder regions on a side opposite to a side of the electronic component. Each of the solder regions is soldered to a substrate by separate solders. The restriction portion is connected to a periphery of the solder regions, and has a level difference relative to the solder regions.

Embodiments are described below in greater detail with reference to the accompanying drawings. These embodiments share the same or similar components. Accordingly, like components are denoted by like reference numerals, and repeated descriptions thereof are omitted.

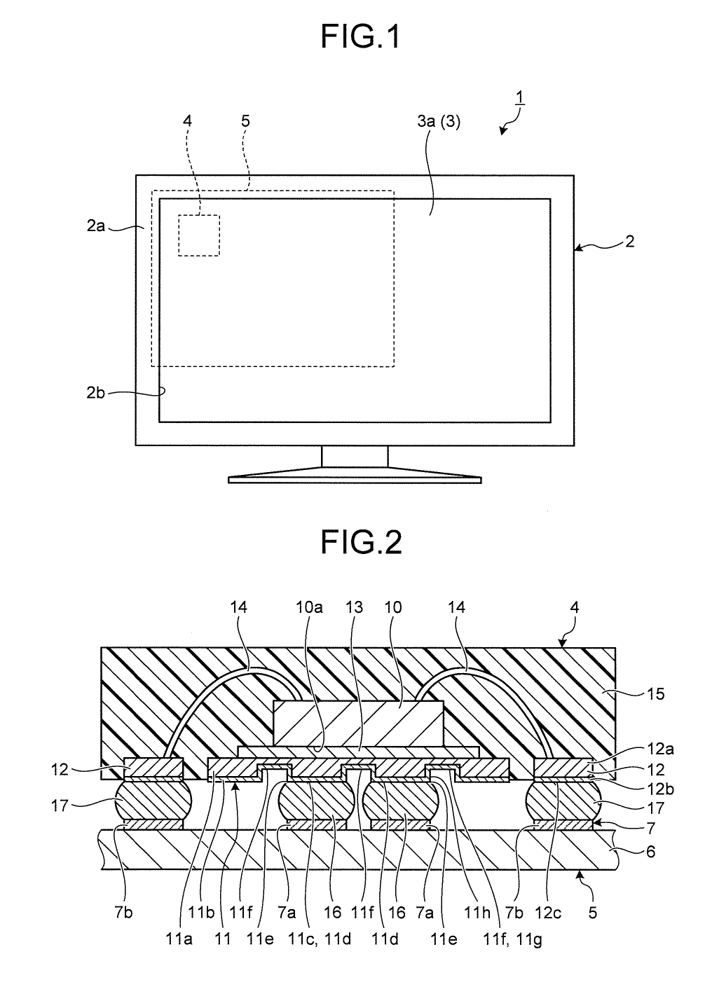

A first embodiment will now be described below with reference to FIGS. 1 to 3.

As illustrated in FIG. 1, a television device 1 serving as an electronic device according to the present embodiment has a rectangular appearance when viewed from the front (in plan view relative to the front surface). The television device 1 comprises a housing 2, a display panel 3 (such as a liquid crystal display (LCD)) serving as a display comprising a display screen 3a exposed to the front from an opening 2b provided at a front surface 2a of the housing 2, and a substrate 5 (such as a printed circuit board) on which a semiconductor package 4 serving as an example of an electronic component structure and the like are mounted. The display panel 3 and the substrate 5 are fixed to the housing 2 with screws or the like, which is not illustrated.

The display panel 3 has a flat parallelepiped shape that is thin in the front-back direction (direction perpendicular to a paper surface in FIG. 1). The display panel 3 is configured to receive a video signal from a video signal processing circuit comprised in a control circuit (both are not illustrated) formed with the semiconductor package 4 and the like mounted on the substrate 5. The display panel 3 then displays video such as a still image and a moving image on the display screen 3a installed at the front surface side. In addition to the video signal processing circuit, he control circuit of the television device 1 comprises a tuner, a high-definition multimedia interface (HDMI) signal processor, an audio video (AV) input terminal, a remote controller signal receiver, a controller, a selector, an on-screen display interface, storage module (such as read-only memory (ROM), random access memory (RAM), and a hard disk drive (HDD)), an audio signal processing circuit, and/or the like, which are not illustrated. The substrate 5 is accommodated in the housing 2 at a rear of the display panel 3. The television device 1 also stores therein an amplifier, a speaker, and/or the like (not illustrated) for outputting audio.

The substrate 5, as illustrated in FIG. 2, comprises an insulating layer 6 made of glass epoxy, or the like, and a wiring pattern 7 formed on the insulating layer 6. The wiring pattern 7 is formed of a conductor such as a copper foil. The wiring pattern 7 comprises a plurality of first electrode pads 7a and a plurality of second electrode pads 7b. The first electrode pads 7a and the second electrode pads 7b are disposed separately from each other. The first electrode pads 7a and the second electrode pads 7b are formed in a rectangular shape.

The semiconductor package 4 is a surface mount device (SMD), and in the present embodiment, as an example, it is formed as a non-lead type semiconductor package without an interposer. The semiconductor package 4, as illustrated in FIG. 2, comprises a semiconductor chip 10 that is an electronic component, a single first electrode 11 that is an electrode connected to the semiconductor chip 10 in a multilayer state, and second electrodes 12 installed at a periphery of the first electrode 11. The first electrode 11 is connected to one surface 10a of the semiconductor chip 10 with a connection layer 13. Each of the second electrodes 12 is connected to the semiconductor package 4 through a metal connection line 14. In the semiconductor package 4, the semiconductor package 4, the first electrode 11, the second electrodes 12, the connection layer 13, and the connection line 14 are integrally formed by a resin sealant 15 for sealing the semiconductor package 4. The semiconductor package 4 is mounted on the substrate 5, while the first electrode 11 is joined to a first electrode pad 7a of the substrate 5 by a first solder 16 that is a solder, and the second electrode 12 is joined to the second electrode pad 7b of the substrate 5 by a second solder 17.

The first electrode 11 and the second electrode 12 have conductivity. The first electrode 11 comprises a lead frame 11a connected to the semiconductor chip 10 with the connection layer 13 and a plated layer 11b placed on the lead frame 11a. The second electrode 12 comprises a lead frame 12a connected to the semiconductor chip 10 with the connection line 14 and a plated layer 12b placed on the lead frame 12a. The lead frames 11a and 12a are made of a copper alloy, nickel, or the like. In the present embodiment, the plated layers 11b and 12b are gold plated layers. The connection layer 13 is formed of a conductive adhesive.

The first electrode 11 is a ground electrode. The first electrode 11 is configured to conduct heat of the semiconductor chip 10 that is a heat generating body to the substrate 5 though the first solder 16. Because the heat is conducted in this manner, the heat of the semiconductor chip 10 is released from the substrate 5. An area of an electrode surface 11c of the first electrode 11 is larger than an area of an electrode surface 12c of the second electrode 12 that is another electrode. Accordingly, high heat dissipation properties can be obtained.

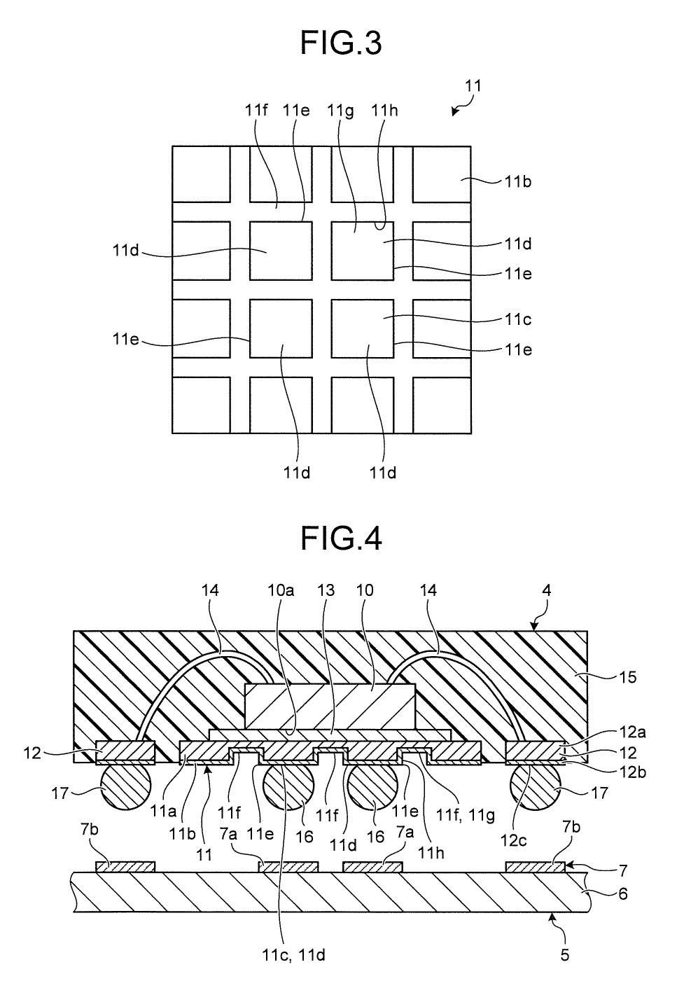

The first electrode 11, as illustrated in FIGS. 2 and 3, is formed in a rectangular shape. The first electrode 11 has a plurality of solder regions 11d on the electrode surface 11c that is a portion on one side of the first electrode 11 opposite to other side of the first electrode 11 to which the semiconductor package 4 is provided. The solder regions 11d are disposed separately from each other. In other words, the solder regions 11d are dispersed on the first electrode 11 that is a single electrode. Each of the solder regions 11d is a region where soldering takes place. The each of the solder regions 11d may entirely be soldered, or a portion thereof may be soldered. In the present embodiment, as an example, there are a total of four solder regions 11d of two rows and two columns (FIG. 3). Each of the solder regions 11d is formed in a rectangular shape. It is preferable that the solder region 11d is formed in the same shape as the first electrode pad 7a to be connected. The solder region 11d is formed on the plated layer 11b. Each of the solder regions 11d is soldered to the substrate 5 by a different first solder 16, and the solder regions 11d are connected to the first electrode pads 7a in one-to-one relationship. The solder region 11d is not limited to the rectangular shape, but may be circular, oval, or the like.

The first electrode 11 comprises a restriction portion 11f connected to a periphery 11e of the solder region 11d. The restriction portion 11f is configured to restrict the movement of the first solder 16 in a melted state by a reflow process in the mounting process of the semiconductor package 4 with respect to the substrate 5. The restriction portion 11f is formed in a concave shape at the first electrode 11, and comprises a level difference relative to the solder regions 11d. The restriction portion 11f is formed in a lattice, and separates the solder regions 11d from one another. The restriction portion 11f encloses the entire periphery of each of the solder regions 11d. A bottom surface 11g and a side surface 11h of the restriction portion 11f are formed with the plated layer 11b. The restriction portion 11f in a concave shape may be formed, for example, by etching, pressing, or cutting.

A mounting process of the semiconductor package 4 formed in this manner to the substrate 5 will now be described. As illustrated in FIG. 4, in the mounting process, as an example, the first solder 16 and the second solder 17 each in a shape of solder ball are joined to the first electrode 11 and the second electrode 12, respectively. The first solder 16 and the second solder 17 are sandwiched between the substrate 5 and the semiconductor package 4. In the reflow step, the first solder 16 and the second solder 17 are heated. Accordingly, the first solder 16 and the second solder 17 are melted. At this time, because the plated layer 11b is a gold plated layer, the first solder 16 in a melted state is well spread over the entire solder region 11d of the first electrode 11 due to the wettability of the solder. In the present embodiment, the restriction portion 11f connected to the periphery 11e of the solder region 11d restricts the movement (spreading) of the first solder 16 in the melted state, thereby preventing the first solder 16 from spreading out to the outside of the solder region 11d. The melted solder spreads out relatively easily on a plane surface. However, if there is a level difference, the melted solder is relatively hardly spreads out because of the surface tension thereof. In the present embodiment, such soldering property is used, and the first solder 16 is restricted from being spread out by forming a level difference with the restriction portion 11f connected to the periphery 11e of the solder region 11d. The first and the second solders 16 and 17 are then cooled and coagulated. In this manner, the semiconductor package 4 is fixed to the substrate 5.

As described above, in the present embodiment, the restriction portion 11f restricts the movement of the first solder 16 in a melted state in the mounting process. Accordingly, it is possible to prevent the melted first solder 16 from being spread over the first electrode 11 excessively. Consequently, in the present embodiment, it is possible to solder the first electrode 11 to the substrate 5 in a suitable manner. As a result, it is possible to enhance the high density of the first solder 16 and the stability (joint reliability) of the first solder 16.

In the present embodiment, the restriction portion 11f in a lattice is used to describe the restriction portion 11f. However, it is not limited thereto and the shape of the restriction portion 11f may be circle, oval, or the like.

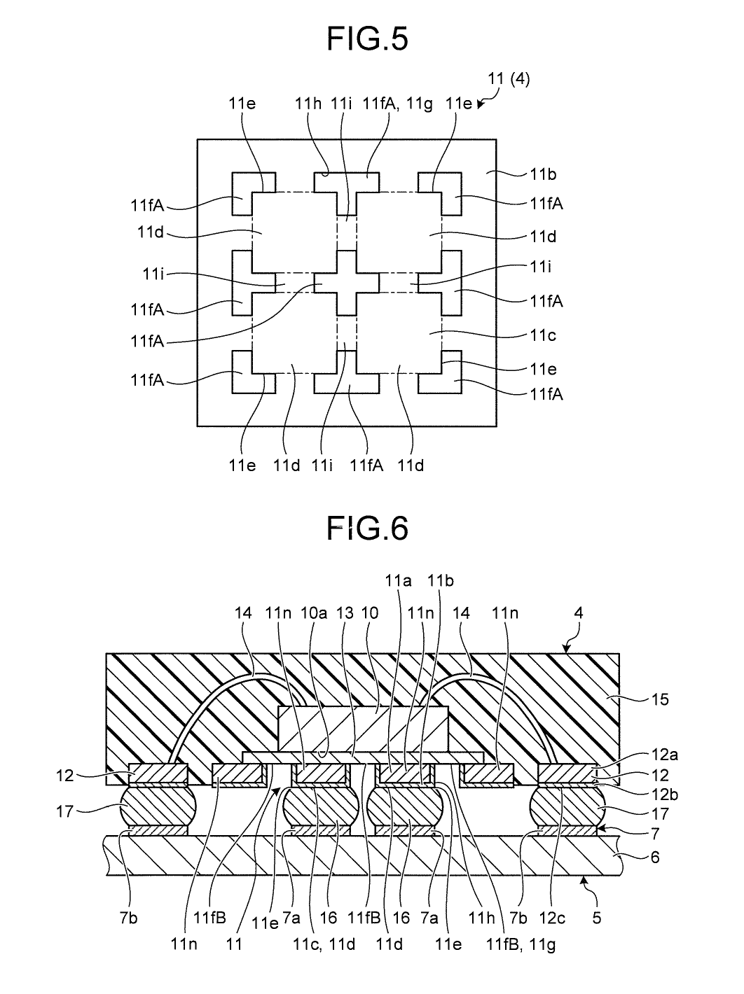

A second embodiment will now be described below with reference to FIG. 5.

The present embodiment is basically the same as the first embodiment, but a shape of a restriction portion 11fA of the semiconductor package 4 is different from that of the first embodiment. As illustrated in FIG. 5, in the present embodiment, the restriction portion 11fA is provided in plurality. The restriction portions 11fA are formed in concave shapes, and are connected to corners of the solder regions 11d. Each of the solder regions 11d is a rectangular region represented by the alternate long and short dash line and the actual line in FIG. 5.

The solder regions 11d are connected to each other with a planar connection surface 11i. The connection surface 11i is formed with the plated layer 11b.

As described above, in the present embodiment also, the restriction portion 11fA is configured to restrict the movement of the first solder 16 (see FIG. 2) in a melted state in the mounting process. Accordingly, it is possible to prevent the melted first solder 16 from being spread over the first electrode 11 excessively. Consequently, in the present embodiment, it is possible to solder the first electrode 11 to the substrate 5 in a suitable manner.

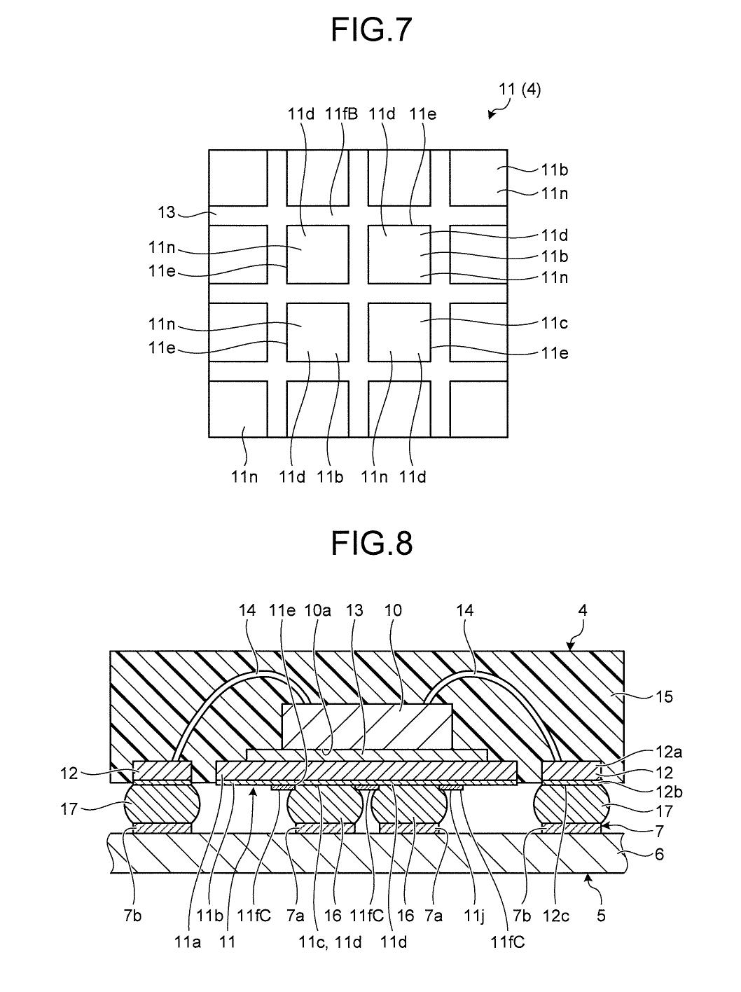

A third embodiment will now be described below with reference to FIGS. 6 and 7.

The present embodiment is basically the same as the first embodiment, but as illustrated in FIGS. 6 and 7, the semiconductor package 4 in the present embodiment comprises the lead frame 11a connected to the semiconductor chip 10 with the connection layer 13, and the plated layer 11b placed on the lead frame 11a and provided with the solder region 11d. The present embodiment is different from the first embodiment in that the bottom surface 11g of a restriction portion 11fB is formed with the connection layer 13. The side surface 11h of the restriction portion 11f is formed with the plated layer 11b the same as that of the first embodiment. Such a restriction portion 11fB can be formed by etching or cutting.

In the present embodiment, the first electrode 11 is divided into a plurality of portions 11n by the restriction portion 11fB. The portions 11n are connected with each other by the connection layer 13.

In the present embodiment described above also, the restriction portion 11fB is configured to restrict the movement of the first solder 16 in a melted state in the mounting process. Accordingly, it is possible to prevent the melted first solder 16 from being spread over the first electrode 11 excessively. Consequently, in the present embodiment, it is possible to solder the first electrode 11 to the substrate 5 in a suitable manner.

In the present embodiment, the bottom surface 11g of the restriction portion 11fB is formed with the connection layer 13, and the side surface 11h of the restriction portion 11fB is formed with the plated layer 11b. However, the embodiment is not limited thereto. For example, the bottom surface and the side surface of the restriction portion in a concave shape may be formed by the lead frame 11a. In this case, for example, the restriction portion may be fabricated by forming a concave in the lead frame 11a, plating the lead frame 11a while masking the concave, and then removing the mask. In the restriction portion, the solder wettability at the side surface of the restriction portion formed by the lead frame 11a is lower than the solder wettability of the plated layer 11b, which is a gold plated layer. As a result, it is also possible to restrict the first solder 16 from being spread out, by the difference of the wettability.

A fourth embodiment will now be described below with reference to FIGS. 8 to 10.

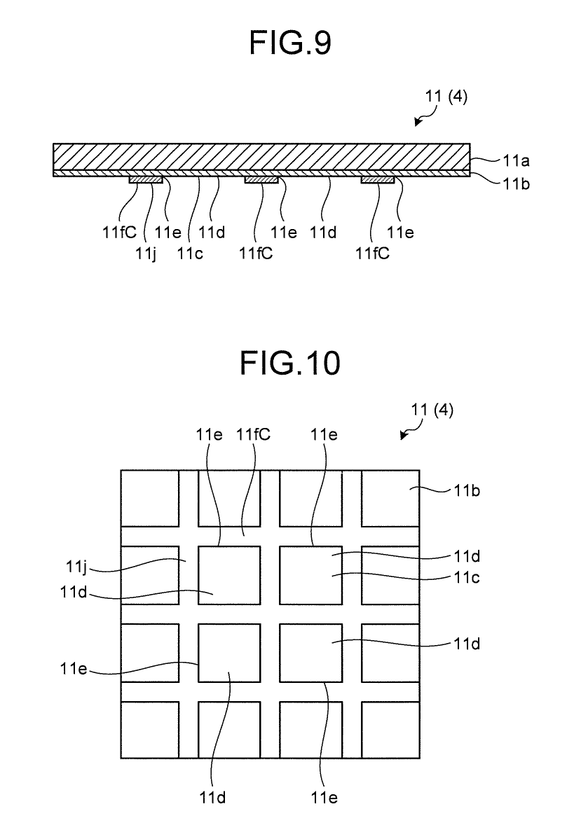

The present embodiment is basically the same as the first embodiment, but a restriction portion 11fC of the semiconductor package 4 is different from that of the first embodiment. The restriction portion 11fC of the present embodiment, as illustrated in FIGS. 8 and 9, is provided with respect to the first electrode 11 in a convex shape. The restriction portion 11fC, as illustrated in FIG. 10, is formed in a lattice.

The semiconductor package 4 of the present embodiment, similar to that of the first embodiment, comprises the lead frame 11a connected to the semiconductor package 4 by the connection layer 13, and the plated layer 11b placed on the lead frame 11a and provided with the solder region 11d. The restriction portion 11fC is formed on the plated layer 11b. The soldering wettability of the restriction portion 11fC is lower than that of the plated layer 11b, which is a gold plated layer. For example, this can be realized by forming the restriction portion 11fC using a material whose solder wettability is lower than that of the material of the plated layer 11b. The material of such restriction portion 11fC may be made of an organic matter, tin or the like. The restriction portion 11fC may also be formed of a solder resist.

The mounting process of the semiconductor package 4 formed in this manner on the substrate 5 is similar to that of the first embodiment. In the reflow step in the mounting process, the restriction portion 11fC restricts the movement (spreading) of the melted first solder 16. Because the restriction portion 11fC of the present embodiment is formed in a convex shape, the restriction portion 11fC serves as an embankment, and restricts the movement of the melted first solder 16. The solder wettability of the restriction portion 11fC is lower than that of the plated layer 11b. In other words, because the solder wettability of the restriction portion 11fC is relatively low, the restriction portion 11fC can also restrict the movement of the first solder 16 in a suitable manner. Further, because the solder wettability of the restriction portion 11fC is relatively low as described above, even when the movement of the first solder 16 in the melted state could not be prevented by the side surface 11h of the restriction portion 11fC, the movement (spreading due to the wettability) on the projected surface 11j of the restriction portion 11fC can be restricted.

As described above, also in the present embodiment, the restriction portion 11fC of the semiconductor package 4 restricts the movement of the first solder 16 in a melted state in the mounting process. Accordingly, it is possible to prevent the melted first solder 16 from being spread over the first electrode 11 excessively. Consequently, in the present embodiment, it is possible to solder the first electrode 11 to the substrate 5 in a suitable manner.

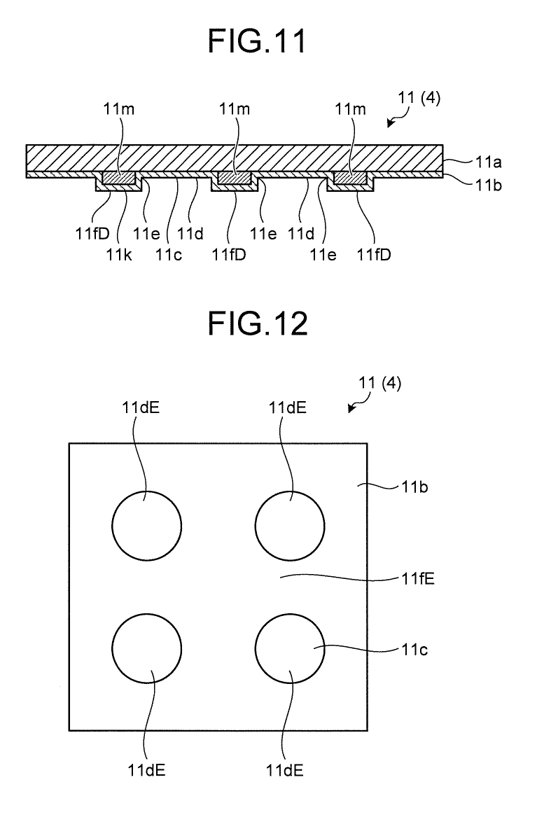

A fifth embodiment will now be described below with reference to FIG. 11.

The present embodiment is basically the same as the fourth embodiment, but a restriction portion 11fD is different from that of the fourth embodiment.

A surface 11k of the restriction portion 11fD of the present embodiment is formed with the plated layer 11b. More specifically, an intermediate layer 11m is formed on a part of the surface of the lead frame 11a at a side of the substrate 5. The restriction portion 11fD in a convex shape is then formed by covering the intermediate layer 11m with the plated layer 11b. The intermediate layer 11m, for example, is formed of metal, and has conductivity.

In the present embodiment described above, the restriction portion 11fD of the semiconductor package 4 also restricts the movement of the first solder 16 (see FIG. 2) in a melted state in the mounting process. Accordingly, it is possible to prevent the melted first solder 16 from being spread over the first electrode 11 excessively. Consequently, in the present embodiment, it is possible to solder the first electrode 11 to the substrate 5 in a suitable manner.

A sixth embodiment will now be described below with reference to FIG. 12.

The present embodiment is basically the same as the fourth embodiment. However, the present embodiment is different from the fourth embodiment in that a solder region 11dE of the semiconductor package 4 is formed in a circular shape, and a restriction portion 11fE formed in a convex shape at the solder region 11dE encloses the entire periphery of the circular solder region 11dE. In other words, the solder region 11dE is formed with the bottom surface of a concave.

In the present embodiment described above, the restriction portion 11fE also restricts the movement of the first solder 16 (see FIG. 2) in a melted state in the mounting process. Accordingly, it is possible to restrict the melted first solder 16 from being spread over the first electrode 11 excessively. Consequently, in the present embodiment, it is possible to solder the first electrode 11 to the substrate 5 in a suitable manner.

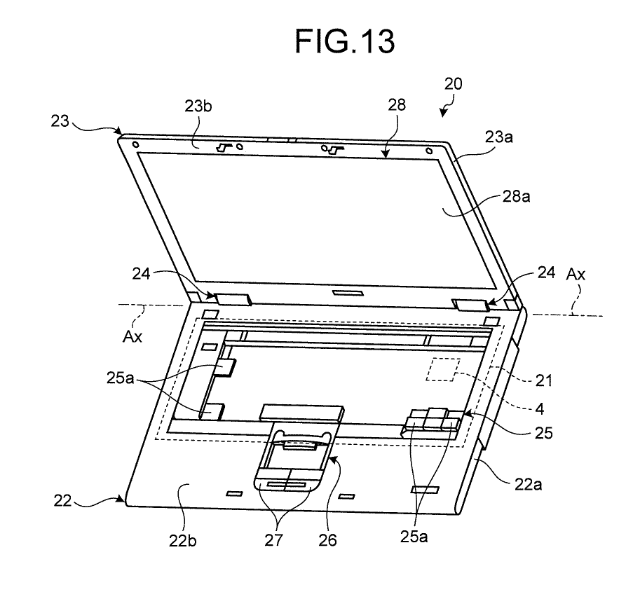

A seventh embodiment will now be described below with reference to FIG. 13.

As illustrated in FIG. 13, an electronic device according to the present embodiment is formed as a so-called note-type personal computer 20, and comprises a first main body 22 in a flat rectangular shape and a second main body 23 in a flat rectangular shape. The first main body 22 and the second main body 23 are rotatably connected with each other through a hinge mechanism 24 so as to be rotated about a rotary shaft Ax, between an opening state illustrated in FIG. 13 and a folded state, which is not illustrated.

The first main body 22 comprises a keyboard 25, a pointing device 26, click buttons 27, and the like, serving as input operation modules. The keyboard 25, the pointing device 26, click buttons 27m, and the like are exposed on a side of a front surface 22b serving as an outer surface of a housing 22a. The second main body 23 comprises a display panel 28 serving as a display device (part). The display panel 28 is exposed on a side of a front surface 23b serving as an outer surface of a housing 23a. The display panel 28, for example, is a liquid crystal display (LCD). When the personal computer 20 is opened, the keyboard 25, the pointing device 26, the click buttons 27, and a display screen 28a of the display panel 28 are exposed, thereby allowing a user to use the personal computer 20. When the personal computer 20 is folded, the front surfaces 22b and 23b are closely facing each other, and the keyboard 25, the pointing device 26, the click buttons 27, the display panel 28, and the like are hidden by the housings 22a and 23a. In FIG. 13, only a part of keys 25a of the keyboard 25 is illustrated.

A substrate 21 similar to the substrate 5 illustrated in the first embodiment is accommodated in the housing 22a of the first main body 22 or the housing 22a of the first main body 22 (in the present embodiment, only in the housing 22a).

The display panel 28 is configured to receive a display signal from a control circuit composed of the semiconductor package 4 and the like mounted on the substrate 21, and displays video such as a still image or a moving image. The control circuit of the personal computer 20 comprises a controller, storage module (such as read-only memory (ROM), random access memory (RAM), and a hard disk drive (HDD)), an interface circuit, various other controllers, and the like. The personal computer 20 also stores therein a speaker and the like (not illustrated) for outputting audio.

The substrate 21 has the similar structure as the substrate 5 in the first embodiment, and the semiconductor package 4 is anyone of the semiconductor package 4 according to the first to the sixth embodiments. In other words, the personal computer 20 serving as an electronic device according to the present embodiment comprises the substrate 21 and the semiconductor package 4 serving as an electronic component structure mounted on the substrate 21. Accordingly, in the personal computer 20 according to the present embodiment also, it is possible to acquire the same effects as those obtained by the first to the sixth embodiments.

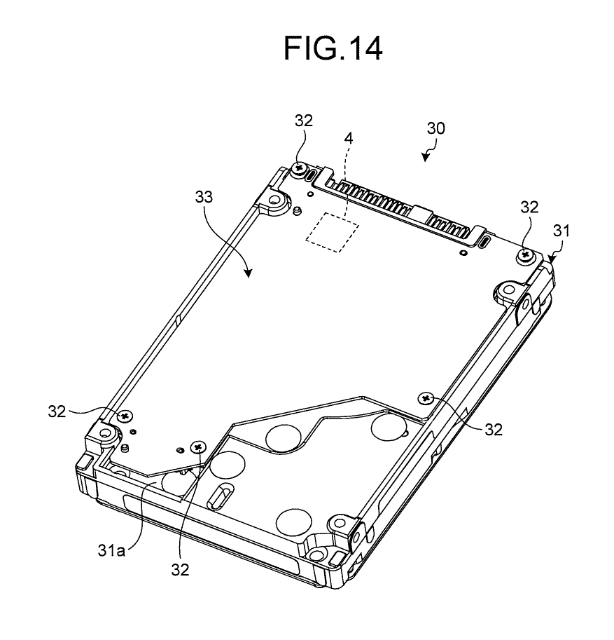

An eighth embodiment will now be described below with reference to FIG. 14.

As illustrated in FIG. 14, an electronic device according to the present embodiment is formed as a magnetic disk device 30. The magnetic disk device 30 comprises a housing 31 in a flat parallelepiped shape for accommodating parts such as a magnetic disk (not illustrated), and a substrate (printed circuit board) 33 fitted to the housing 31 by fasters such as screws 32.

The substrate 33 is disposed on an upper wall 31a of the housing 31. A film-like insulating sheet (not illustrated) is interposed between the substrate 33 and the upper wall 31a. In the present embodiment, the rear surface of the substrate 33 when viewed in FIG. 16, in other words, the rear surface (not illustrated) of the substrate 33 facing the upper wall 31a is the main mounting surface on which a plurality of electronic components and the like including the semiconductor package 4 are mounted. A wiring pattern (not illustrated) is formed on the front and rear surfaces of the substrate 33. The electronic components can also be mounted on the front surface of the substrate 33.

In the present embodiment also, the substrate 33 has the similar structure as that of the first embodiment, and the semiconductor package 4 mounted on the substrate 33 is any one of the semiconductor package 4 from the first to the sixth embodiments. In other words, the magnetic disk device 30 serving as an electronic device according to the present embodiment comprises the substrate 33 and the semiconductor package 4 serving as an electronic component structure mounted on the substrate 33. Accordingly, in the magnetic disk device 30 according to the present embodiment also, it is possible to acquire the same effects as those obtained by the first to the sixth embodiments.

As described above, in the embodiments, it is possible to provide the electronic component structure and the electronic device capable of soldering the electrode to the substrate in a suitable manner.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic component structure comprising:
an electronic component;
an electrode connected to the electronic component in a multilayer state and comprises a plurality of solder regions on a side opposite to a side of the electronic component, each of the solder regions being soldered to a substrate by separate solders; and
a restriction portion connected to a periphery of the solder regions, and comprising a level difference relative to the solder regions.

2. The electronic component structure of claim 1, wherein the restriction portion is formed in a concave shape at the electrode.

3. The electronic component structure of claim 2, wherein
the electrode comprises: a lead frame connected to the electronic component; and a plated layer comprising the solder regions and placed on the lead frame, and
a bottom surface and a side surface of the restriction portion are formed with the plated layer.

4. The electronic component structure of claim 2, wherein
the electrode comprises: a lead frame connected to the electronic component with a connection layer; and a plated layer layered on the lead frame and provided with the solder regions, and
a bottom surface of the restriction portion is formed with the connection layer, and a side surface of the restriction portion is formed with the plated layer.

5. The electronic component structure of claim 1, wherein the restriction portion is formed in a convex shape at the electrode.

6. The electronic component structure of claim 5, wherein
the electrode comprises: a lead frame connected to the electronic component; and a plated layer layered on the lead frame and provided with the solder regions, and
the restriction portion is formed on the plated layer.

7. The electronic component structure of claim 5, wherein
the electrode comprises: a lead frame connected to the electronic component; and a plated layer layered on the lead frame and provided with the solder regions, and
a front surface of the restriction portion is formed with the plated layer.

8. The electronic component structure of claim 1, wherein the restriction portion is configured to separate the solder regions from one another.

9. The electronic component structure of claim 8, wherein the restriction portion is formed in a lattice.

10. The electronic component structure of claim 1, wherein
the restriction portion is provided in plurality, and
the solder regions are connected to each other through a planar connection surface.

11. An electronic device comprising:
a substrate; and
the electronic component structure of claim 1 configured to be mounted on the substrate.
